(19) United States
(12) Patent Application Publication
(10) Pub. No.: US 2008/0054354 A1
(43) Pub. Date: Mar. 6, 2008

(54) PHOTO MASK, SEMICONDUCTOR INTEGRATED CIRCUIT DEVICE, AND METHOD OF MANUFACTURING THE SAME

(75) Inventors: Ho-Jin OH, Seoul (KR); Jee-Eun JUNG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/849,928

(22) Filed: Sep. 4, 2007

(30) Foreign Application Priority Data
Sep. 4, 2006 (KR) 2006-0084853

(51) Int. Cl. H01L 29/78; G03F 9/00; H01L 21/336

(52) U.S. Cl. 257/334; 430/5; 438/270; 257/E29.262; 257/E21.41

(57) ABSTRACT

A photo mask, a semiconductor integrated circuit, and a method of manufacturing the same are provided. The photo mask includes light transmitting rows and recess trenches, respectively, that include a short region in every other light transmitting row. In the semiconductor integrated circuit, the short region may include a dummy transistor so that short-circuiting bridges that may occur between adjacent recess trenches will not adversely affect the operations of the semiconductor integrated circuit.

### CROSS REFERENCE TO RELATED APPLICATION

This application claims priority from Korean Patent Application No. 10-2006-0084853 filed on Sep. 4, 2006 in the Korean Intellectual Property Office, the disclosure of which is incorporated herein by reference in its entirety.

### BACKGROUND OF THE INVENTION

1. Field of the Invention

The present invention relates to a semiconductor integrated circuit device and a method of manufacturing the same, and more particularly, to a semiconductor integrated circuit device and a method of manufacturing the same which are capable of improving productivity.

2. Description of the Related Art

With large scale integration of semiconductor devices, an incorporated MOS device is increasingly reduced in size. Further, to improve the operation speed of the device and a current driving capacity, the length of a channel in the MOS device may decrease to well below a sub-micron level.

As the length of the channel decreases, a depletion region of a source electrode and a drain electrode begins to enter the channel, reducing an active channel length. For this reason, a threshold voltage may be reduced to a point where a short channel effect occurs, which eliminates control of the gate of the MOS transistor. In addition, during the operation of the transistor, source and drain electrode impurities may be diffused to the sides, contributing to a punch-through effect.

In particular, as a design rule is reduced, the short channel effect causes a leakage current leading to an increase of an ion implantation amount, which makes it difficult to secure a refresh time.

Accordingly, to secure a sufficient channel length, it is known that a recess channel array transistor (RCAT) can increases the channel length by forming a recess channel trench in a region where the channel of the transistor is formed.

When manufacturing the recess channel array transistor, a plurality of recess trenches are formed extending in one direction. To form the recess trenches, an etching process is performed, but an etching amount for a termination region of each of the recess trenches may be detrimentally larger than other regions. Accordingly, adjacent recess trenches may be mistakenly connected to each other and a bridge may occur. The bridge may cause a short circuit of the semiconductor device, which may result in a defective semiconductor device.

To further exacerbate this problem, a recess trench having a spherical bottom is often used. Since the width of the lower part of the recess trench is larger than the width in the general recess trench, the bridge may easily occur.

### SUMMARY OF THE INVENTION

An object of the present invention is to provide a photo mask capable of improving productivity.

Another object of the present invention is to provide a semiconductor integrated circuit device capable of improving productivity.

Still another object of the present invention is to provide a method of manufacturing a semiconductor integrated circuit device capable of improving productivity.

Objects of the present invention are not limited to those mentioned above, and other objects of the present invention will be apparently understood by those skilled in the art through the following description.

In an embodiment, a photo mask comprises a light transmissive substrate, a main light blocking pattern formed on the substrate and defining first and second light transmitting rows, the first and second light transmitting rows being adjacent to each other, and an auxiliary light blocking pattern dividing each of the first light transmitting rows into a long portion and a short portion. The first and second light transmitting rows may be alternately arranged and parallel.

In another embodiment, a method of forming a semiconductor integrated circuit includes forming dummy transistors in short portions of first rows disposed on a semiconductor substrate, using the method of the embodiment described above.

In still another embodiment, a semiconductor integrated circuit comprises a semiconductor substrate, a first recess trench extending in a first direction on the semiconductor substrate, a second recess trench adjacent to the first recess trench, having a length smaller than the first recess trench, and having one end aligned with one end of the first recess trench in a second direction, and a third recess trench having one end opposite to the other end of the second recess trench, the second and third trenches aligned with each other in the first direction. The third recess trenches may be spherical recess trenches. Termination widths of the first, second, and third recess trenches may be larger than the width of other regions of the first, second, and third recess trenches, respectively.

In still another embodiment, a method of manufacturing a semiconductor integrated circuit comprises forming the photo mask as explained above, and forming recess trenches in a semiconductor substrate using the photo mask to block light.

### BRIEF DESCRIPTION OF THE DRAWINGS

The above and other features and advantages of the present invention will become more apparent by describing in detail preferred embodiments thereof with reference to the attached drawings in which:

FIG. 1 is a plan view schematically illustrating a photo mask according to an embodiment of the invention;

FIGS. 2 to 5 are views illustrating a method of manufacturing a recess trench using the photo mask according to an embodiment of the invention;

FIG. 6 is a plan view schematically illustrating a photo mask according to another embodiment of the invention;

FIG. 7 is a plan view schematically illustrating a photo mask according to still another embodiment of the invention;

FIG. 8 is a plan view schematically illustrating a photo mask according to yet another embodiment of the invention;

FIG. 9 is a cross-sectional view illustrating a recess channel array transistor of a semiconductor integrated circuit device according to still another embodiment of the invention; and

FIG. 10 is a cross-sectional view illustrating a spherical recess channel array transistor of a semiconductor integrated circuit device according to still another embodiment of the invention.

### DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

Like reference numerals refer to like elements throughout the specification. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

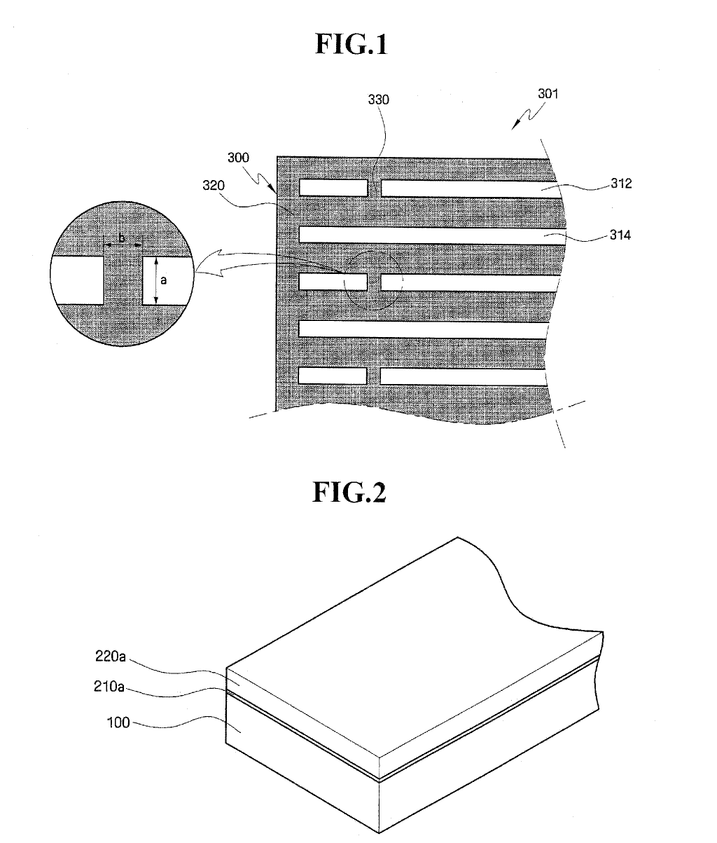

Hereinafter, a photo mask 301 according to an embodiment of the invention will be described with reference to FIG. 1, which is a plan view schematically illustrating the photo mask 301.

Referring to FIG. 1, the photo mask 301 includes a light transmissive substrate 300, a main light blocking pattern 320, and a first auxiliary light blocking pattern 330.

The light transmissive substrate 300 has a pattern for dividing a light transmitting region and a light blocking region formed thereon. For example, a light transmissive quartz substrate or a transparent glass substrate may be used as the light transmissive substrate 300. Other options are well known in the art.

The main light blocking pattern 320 is formed on the light transmissive substrate 300 and defines a substantial form of a pattern to be transferred on a surface of a semiconductor substrate. The main light blocking pattern 320 may be formed by disposing non-transmissive materials, such as chrome, oxidized steel, or thin film silicon on the light transmissive substrate 300. That is, the light blocking regions are formed by disposing a non-transmissive material on the light transmissive substrate 300, while non-coated regions are light transmitting.

The main light blocking pattern 320 defines a first light transmitting region or row 312 and a second light transmitting region or row 314 in which recess trenches principally extend in one direction. The first light transmitting region 312 and the second light transmitting region 314 are adjacent to each other and extend in parallel in a preferred embodiment. The first and second light transmitting regions 312 and 314 defined by the main light blocking pattern 320 may be alternately arranged, as in the embodiment of FIG. 1.

A first auxiliary light blocking pattern 330 is formed in the first light transmitting region 312. That is, the first auxiliary light blocking pattern 330 is formed to block a part of the first light transmitting region 312. In a first embodiment, a width “a” in one direction of the first auxiliary light blocking pattern 330 is the same as the width of the first light transmitting region 312. A width “b” in another direction of the first auxiliary light blocking pattern 330 is larger than the resolution of an exposure.

Hereinafter, a method of manufacturing a recess trench by using the photo mask according to an embodiment of the invention will be described with reference to FIGS. 1 to 5.

FIGS. 2 to 5 are views showing the method of manufacturing a recess trench by using the photo mask.

First, referring to FIG. 2, a pad insulating film 210a and a mask film 220a are formed on a semiconductor substrate 100.

The pad insulating film 210a may be formed using an oxidation process. For example, the pad insulating film 210a may be formed of an MTO (Medium Temperature Oxide) film that is formed at a temperature of approximately 400° C. The mask film 220a may be formed using a chemical vapor deposition method. For example, the mask film 220a may be formed of polysilicon, SiN, or SiON.

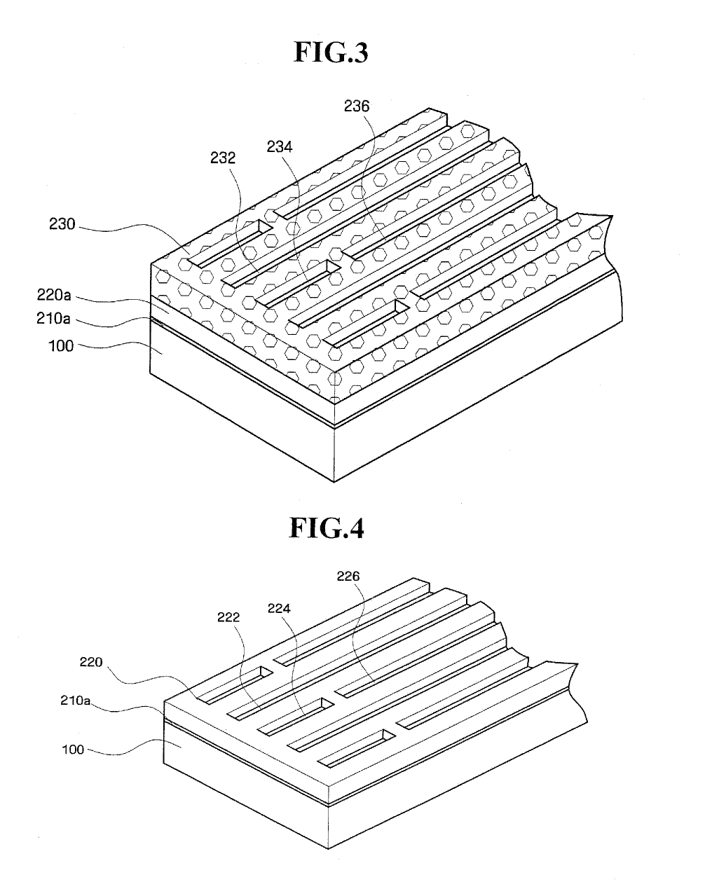

Next, referring to FIG. 3, a photoresist pattern 230 is formed on the mask film 220a.

First, the photoresist is coated on the mask film 220a. Next, a photolithography process is performed by using the photo mask 301 according to the embodiment of the invention shown in FIG. 1. When the photolithography process is performed by using the photo mask 301, photoresist in regions corresponding to the first and second light transmitting regions 312 and 314 of the photo mask 301 is removed. At this time, the photoresist in a region where the first auxiliary light blocking pattern 330 of the first light transmitting region 312 is formed is not removed. Thereafter, first to third regions 232, 234, 236 in which the photoresist is removed are formed in the photoresist pattern 230. The first region 232 principally extends in one direction. The second region 234 is adjacent to the first region 232. However, the length of the second region 234 may be shorter than that of the first region 232 and one end of the second region 234 may be aligned with one end of the first region 232. Further, the third region 236 may be aligned to the second region 234 in one direction and one end of the third region 236 may be opposite to the other end of the second region 234. The first to third regions 232, 234, and 236 may be alternately arranged in the other direction.

The second region 234 may include a dummy transistor. Even though transistors to be actually used are not formed in the second region 234, the photolithography process can be performed in the same condition as in other regions of the first region 232 when patterning an end portion of the first region 232 by forming the second region 234. Therefore, the second region 234 may serve as the dummy for maintaining the uniform width of the first region 232.

Referring to FIG. 4, a mask film pattern 220 is formed by patterning the mask film (220a of FIG. 3).

That is, the mask film pattern 220 is formed by patterning the mask film 220a using the photoresist pattern 230 as an etching mask. The mask film pattern 220 may be formed the same way as the photoresist pattern 230. That is, the mask film pattern 220 includes first to third patterns 222 to 226. The first pattern 222 principally extends in one direction. The second pattern 224 is adjacent to the first pattern 222 and has a length shorter than that of the first pattern 222. One end of the second pattern 224 may be aligned to one end of the first pattern 222. Further, the third pattern 226 may be aligned to the second pattern 224. One end of the third pattern 226 is adjacent to the other end of the second pattern 224. The first to third patterns 222, 224, and 226 may be alternately arranged.

Next, the photoresist pattern 230 may be removed by using an ashing process or other process well known in the art.

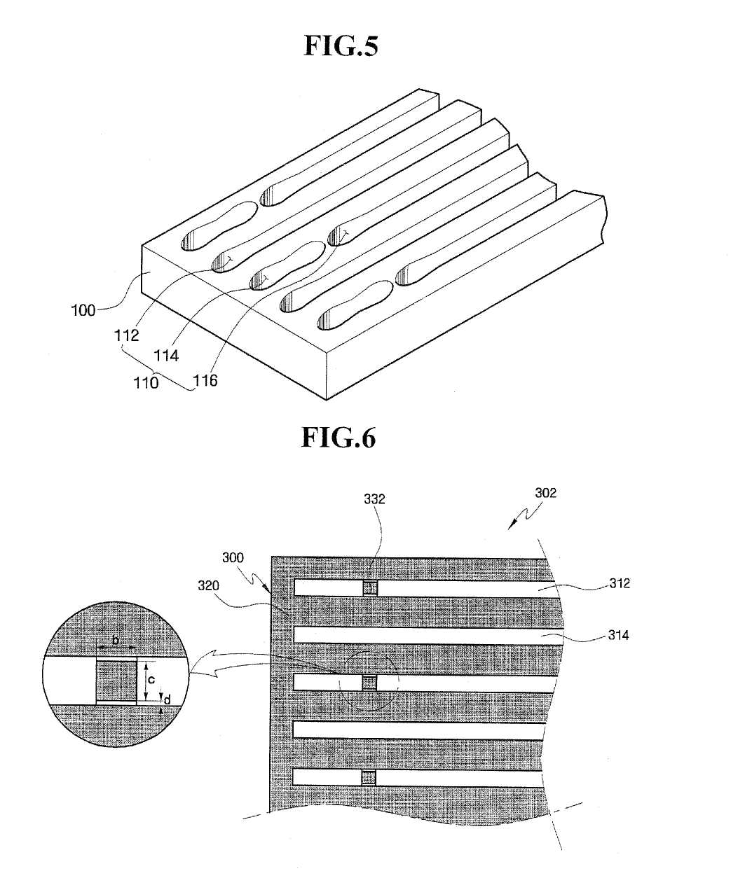

Referring to FIG. 5, first to third trenches 112, 114, and 116 are formed by etching the semiconductor substrate 100.

That is, the recess trenches 110 are formed by etching the pad insulating film (210a of FIG. 4) and the semiconductor substrate 100 using the mask film pattern 220 as an etching mask. At this time, the pad insulating film 210a and the semiconductor substrate 100 may be etched by dry etching. Next, the mask film pattern 220 and the pad insulating film pattern 210 may be removed.

Then, a plurality of the first to third recess trenches 112, 114, and 116 formed on the semiconductor substrate 100 are exposed.

The first recess trench 112 principally extends in one direction. The second recess trench 114 is adjacent to the first recess trench 112. The length of the second recess trench 114 is shorter than that of the first recess trench 112 and one end of the second recess trench 114 may be aligned to one end of the first recess trench 112.

The third recess trench 116 may be aligned to the second recess trench 114 and one end of the third recess trench 116 may be adjacent to the other end of the second recess trench 114.

That is, the second recess trench 114 and the third recess trench 116 may be formed to be aligned while being adjacent to the first recess trench 112. Further, the first to third recess trenches 112, 114, and 116 may be alternately arranged. Here, the widths of ends of the first to third recess trenches 112, 114, and 116 may be larger than the other regions, as indicated in FIG. 5.

Hereinafter, a photo mask 302 according to another embodiment of the invention will be described with reference to FIG. 6, which is a plan view schematically illustrating the photo mask 302. The same reference numerals will be used to indicate the same components shown in FIG. 1 and a detailed description of the corresponding components will be omitted.

Referring to FIG. 6, the photo mask 302 is different from the photo mask (301 of FIG. 1) of the last-described embodiment in that the photo mask 302 includes a second auxiliary light blocking pattern 332.

The second auxiliary light blocking pattern 332 is formed in the first light transmitting region 312 to block a part of the first light transmitting region 312. A width “c” of the second auxiliary light blocking pattern 332 is shorter than that of the first light transmitting region 312, but larger than the resolution of exposure. The width “b” of the second auxiliary light blocking pattern 332 is also larger than the resolution of the exposure. Further, a gap “d” between the second auxiliary light blocking pattern 332 and the main light blocking pattern is smaller than the resolution of the exposure. FIG. 6 shows a case in which the second auxiliary light blocking pattern 332 is rectangular. However, the second auxiliary light blocking pattern 332 is not limited to this shape, and may be, for example, a polygon in which its width is larger than the resolution of the exposure.

Hereinafter, a method of manufacturing a recess trench by using the photo mask according to another embodiment of the invention will be described with reference to FIGS. 2 to 6.

Referring to FIG. 2, the pad insulating film 210a and the mask film 220a may be formed on the semiconductor substrate 100 in the same way as previously explained.

Next, referring to FIG. 3, the photoresist pattern 230 is formed on the mask film 220a.

In particular, first, the photoresist is coated on the mask film 220a. Next, a photolithography process is performed by using a photo mask 302 (shown in FIG. 6) according to another embodiment of the invention. When the photolithography process is performed by using the photo mask 302, a photoresist corresponding to the first and second light transmitting regions 312 and 314 of the photo mask 302 is removed. The photoresist is not removed in a region where the second auxiliary light blocking pattern 332 is formed in the second light transmitting region 314.

The size of the gap “d” between the main light blocking pattern 320 and the second auxiliary light blocking pattern 332 existing on the photo mask 302 is smaller than the resolution of the exposure. Therefore, the region where the main light blocking pattern 320 is separated from the second auxiliary light blocking pattern 332 by the gap “d” is not patterned by the photoresist pattern 230. Accordingly, the second auxiliary light blocking pattern 332 in which the photoresist is not removed is connected to a region where the photoresist is not removed from the main light blocking pattern 332. That is, the mask is formed in the same way as the photoresist pattern 230 formed by using the mask according to the last embodiment.

First to third regions 232, 234, and 236 in which the photoresist is removed are formed in the photoresist pattern 230, as explained for the embodiment of FIG. 3.

Referring to FIGS. 4 and 5, the mask film (220a of FIG. 3) is patterned to form the mask film pattern 220. The photoresist pattern 230 may be removed by an ashing process, and the semiconductor substrate 100 may be etched to form the first to third recess trenches 112, 114, and 116 in the same way as the method of manufacturing the recess trench 110 by using the photo mask 301 of FIG. 1.

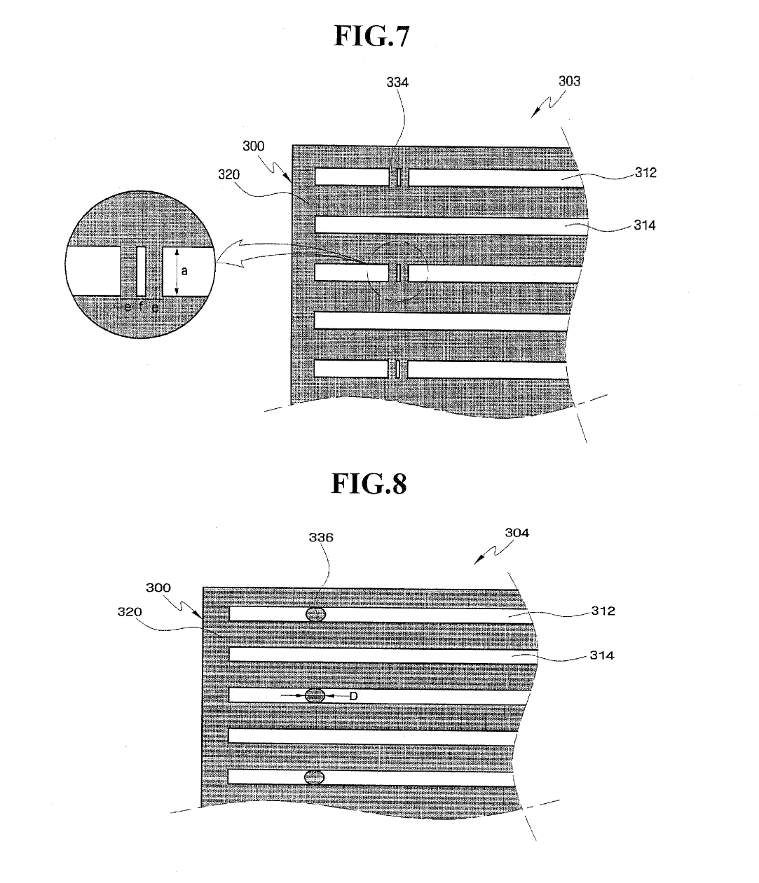

Hereinafter, a photo mask 303 will be described according to still another embodiment of the invention with reference to FIG. 7, which is a plan view schematically illustrating the photo mask 303. The same reference numerals will be used to indicate the same components shown in FIG. 1, and a detailed description of the corresponding components will be omitted.

Referring to FIG. 7, the photo mask 303 is different from the photo mask 301 of FIG. 1 in that the photo mask 303 includes a third auxiliary light blocking pattern 334.

The third auxiliary light blocking pattern 334 is formed in the first light transmitting region 312 to block a part of the first light transmitting region 312. A plurality of third auxiliary light blocking patterns 334 may be formed in the first light transmitting region 312. The width “a” of the third auxiliary light blocking pattern 334 may be equal to that of the first light transmitting region 312, and a width “e” of the third auxiliary light blocking pattern 334 may be larger than the resolution of the exposure. Further, a gap “f” between the plurality of third auxiliary light blocking patterns 334 is less than the resolution of the exposure. In this embodiment, two third auxiliary light blocking patterns 334 having the same width are showed in FIG. 7, but the widths of each of the plurality of the third auxiliary light blocking patterns 334 may be different from one another.

Hereinafter, a method of manufacturing the recess trench by using the photo mask according to the embodiment of FIG. 7 will be described with reference to FIGS. 2 to 5 and 7.

As described earlier for the previous embodiments, the pad insulating film 210a and the mask film 220a are formed on the semiconductor substrate 100. Next, the photoresist pattern 230 is formed on the mask film 220a.

The photoresist is coated on the mask film 220a. Next, a photolithography process is performed by using the photo mask 303 shown in FIG. 7. When the photolithography process is performed by using the photo mask 303, a photoresist corresponding to the first and second light transmitting regions 312 and 314 of the photo mask 303 is removed. However, in the second light transmitting region 314, the photoresist is not removed in a region where the third auxiliary light blocking pattern 334 is formed. At this time, the width “e” of the third auxiliary light blocking pattern 334 is larger than the resolution of the exposure, but the gap “f” between the plurality of third auxiliary light blocking patterns 334 is smaller than the resolution of the exposure. Therefore, the third auxiliary light blocking pattern 334 is not patterned exactly as it was manufactured. Accordingly, the photoresist is not removed from regions between the plurality of third auxiliary light blocking patterns 334 as well as regions where the third auxiliary light blocking patterns 334 are formed. That is, the mask is formed in the same way as the photoresist pattern 230 formed by using the mask as described in an earlier embodiment.

First to third regions 232, 234, and 236 in which the photoresist is removed are formed in the photoresist pattern 230 as shown in FIG. 3.

Referring to FIGS. 4 and 5, the mask film 220a of FIG. 3 is patterned to form the mask film pattern 220. The photoresist pattern 230 is removed by an ashing process, for example, and the semiconductor substrate 100 is etched to form the first to third recess trenches 112, 114, and 116 in the same way as described earlier using the photo mask 301 of FIG. 1.

Hereinafter, a photo mask 304 will be described according to another embodiment of the invention with reference to FIG. 8, which is a plan view schematically illustrating the photo mask 304. The same reference numerals will be used to indicate the same components shown in FIG. 1, and a detailed description of the corresponding components will be omitted.

Referring to FIG. 8, the photo mask 304 is different from the photo mask 301 of FIG. 1 in that the photo mask 303 includes a fourth auxiliary light blocking pattern 336.

The fourth auxiliary light blocking pattern 336 is formed in the first light transmitting region 312 to block a part of the first light transmitting region 312. A plurality of fourth auxiliary light blocking patterns 336 may be formed in the first light transmitting region 312. The fourth auxiliary light blocking pattern 336 may have a circular or elliptical shape. Here, a diameter of the fourth auxiliary light blocking pattern 336 is larger than the resolution of the exposure.

A method of manufacturing a recess trench using the photo mask 304 is similar to the methods described for previous embodiments with reference to FIGS. 2 to 5.

Hereinafter, a semiconductor integrated circuit device according to one embodiment of the invention will be described with reference to FIGS. 5 to 9.

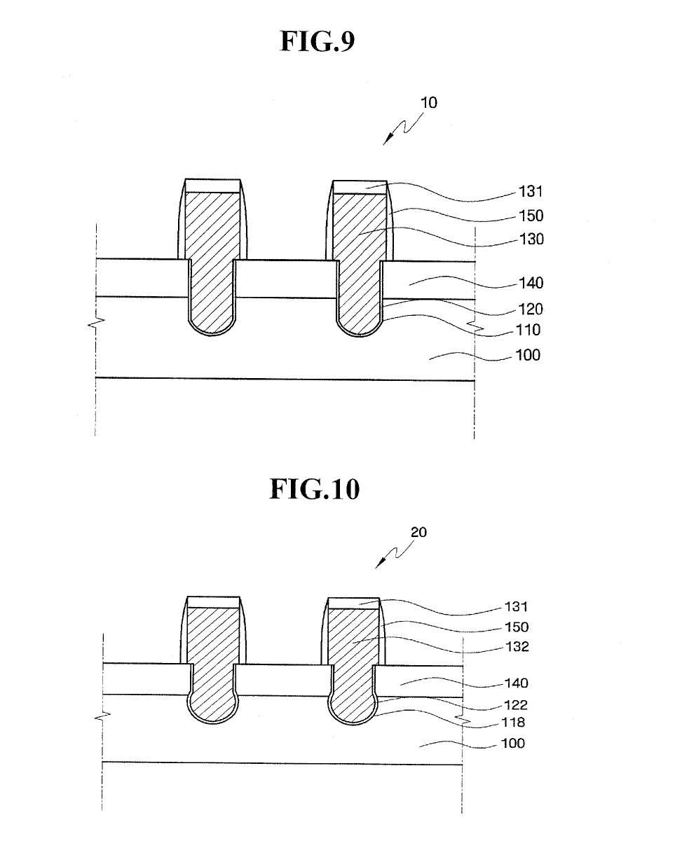

FIG. 9 is a cross-sectional view illustrating a recess channel array transistor of a semiconductor integrated circuit device.

Referring to FIG. 9, a substrate is divided into an active region and an isolation region by an isolation film of STI (shallow trench isolation) or FOX (field oxide). A recess channel array transistor 10 is formed in the active region.

The recess channel array transistor 10 includes a recess trench 110, a gate insulating film 120, a gate electrode 130, a source/drain region 140, and spacers 150.

The recess trench 110 is formed to be relatively narrow and deep in the semiconductor substrate 100. The recess trench 110 will be described below in detail.

The gate insulating film 120 is formed uniformly on the inner surface of the recess trench 110. The gate insulating film 120 may be, for example, a silicon oxide film (SiOx), a silicon oxynitride film (SiON), a titanium oxide film (TiOx), or a tantalum oxide film (TaOx).

The gate electrode 130 is provided on the gate insulating film 120 to fill the recess trench 110 and to protrude above the recess trench 110. The gate electrode 130 may be formed by sequentially laminating polysilicon, gate metal, and the like on the gate insulating film 140, and may have a capping film 131 at its upper part. At this time, the width of the gate electrode 130 protruding above the recess trench 110 may be slightly larger than the width of the recess trench 110.

The source/drain region 150 in which an impurity is implanted is provided in the active regions at both sides of the gate electrode 130. When the recess channel array transistor 10 is an N type transistor, the source/drain region 150 may be formed by ion-implanting N-type impurities.

The spacers 150 are provided at both side walls of the protruding gate electrode 130. The spacers 150 may be formed of a nitride film (SiN) or an oxide film (SiO₂).

Hereinafter, a method of manufacturing a recess channel array transistor according to an embodiment of the invention will be described with reference to FIGS. 1 to 5 and 9.

First, as described earlier with reference to FIGS. 1 to 5, the pad insulating film 210a and the mask film 220a are formed on the semiconductor substrate 100. The photoresist pattern 230 is formed on the mask film 220a by using the photo mask according to an embodiment of the invention. The mask film 220a is patterned to form the mask film pattern 220. The semiconductor substrate 100 is etched to form the recess trench 110.

Next, referring to FIG. 9, the gate insulating film 120, the gate electrode 130, and the source/drain region 150 are formed, so that the recess channel array transistor 10 is completed.

Specifically, the gate insulating film 120 is uniformly formed on the inner surface of the recess trench 110. The gate insulating film 120 is formed of, for example, a silicon oxide film, a silicon oxynitride film, a titanium oxide film, or a tantalum oxide film. The gate insulating film 120 may be deposited using a chemical vapor deposition method or a sputtering method.

Next, the gate electrode 130 is formed on the gate insulating film 120. The gate electrode 130 may be formed by depositing polysilicon, a metal film, and the like on the gate insulating film 120 to form the capping film 131 and patterning the gate insulating film 1203 the polysilicon, the metal film, and the like with the capping film 131.

Next, the gate electrode 130 and the source/drain region are formed, so that the recess channel array transistor 10 is completed.

Next, the spacers 150 may be formed on the sides of the gate electrode 130. The spacers 150 are formed by depositing a nitride film (SiN) or an oxide film (SiO₂) using a chemical vapor deposition (CVD) method and performing anisotropy etching.

Next, the source/drain region 150 may be formed to be aligned with the gate electrode 130. And the recess channel array transistor 10 is completed. The source/drain region 150 is formed by implanting an impurity into both sides of the gate electrode 130 on the active region.

For an N-type MOS transistor, to form the source/drain region 150, arsenic ions or phosphorous ions may be implanted at a high concentration and with an energy in the order of tens of KeV. Further, for a P-type MOS transistor, to form the source/drain region 150, boron ions may be implanted at a high concentration and with an energy in the order of tens of KeV.

As mentioned above with reference to FIG. 5, a region where the recess trench 110 is formed may be a region where a dummy transistor is formed.

Here, the widths of ends of the first to third recess trenches 112, 114, and 116 are larger than the widths of other regions. If the widths of the first recess trench 112 and the second recess trench 114 become too large, termination regions of the first recess trench 112 and the second recess trench 114 may join and be connected to each other, resulting in a bridge. However, in the semiconductor integrated circuit device according to an embodiment of the invention, the second recess trench 114 is separated from the third recess trench 116. Therefore, even if the first recess trench 112 is connected to the second (orphan) recess trench 114, the elements are not short-circuited. This is because the region that includes the second recess trench 114 is the region where the dummy transistor may be formed.

Therefore, even though a bridge may occur, a defective semiconductor integrated circuit device will not result. Accordingly, manufacturing productivity can improve. That is, the terminal ends of the active portion of the trenches are staggered to minimize possible short circuit effects that could occur between devices formed within active regions if formed within two adjacent rounded (e.g. the spherical recess channels) ends as in the prior art.

Hereinafter, a semiconductor integrated circuit device according to another embodiment of the invention will be described with reference to FIG. 10, which is a cross-sectional view showing a spherical recess channel array transistor in a semiconductor integrated circuit device.

The same parts as those of FIG. 9 are represented by the same reference numerals, and a description thereof will be omitted. The semiconductor integrated circuit device according to the present embodiment is different than the semiconductor integrated circuit device according to the earlier embodiment in that a spherical recess trench is provided.

Referring to FIG. 10, a semiconductor integrated circuit device includes a spherical recess channel array transistor 20 having a spherical recess trench 118. The spherical recess trench 118 is a recess trench having a spherical bottom.

Since the spherical recess trench 118 has a spherical bottom, the width of the lower part of the trench is larger than the width of the general recess trench. Accordingly, terminations that are larger than the widths of other regions may be connected to each other, resulting in a bridge. Accordingly, a defective semiconductor integrated circuit device may easily occur.

However, in the semiconductor integrated circuit device according to the embodiment of the invention, even though the spherical recess trenches 118 may be connected to each other with a bridge, the integrated circuit elements are not short-circuited because of the presence of a dummy element, such as the dummy transistor described above.

Meanwhile, since the spherical recess trench 118 has the spherical bottom, it has a radius of curvature larger than the general recess trench, and the channel length increases. Further, as the radius of curvature increases, the concentration of an electric field can be prevented, and a refresh time characteristic of the semiconductor integrated circuit device can be improved. In addition, since the channel length increases, and the refresh time characteristic is improved, the transistor can more stably operate.

A method of manufacturing the semiconductor integrated circuit device according to the present embodiment is now described with reference to FIGS. 2 to 5 and FIG. 10 by highlighting differences with the earlier embodiments.

The bottom of the recess trench 110 is etched isotropically to form the spherical recess trench 118. The isotropic etching may be performed by dry etching.

Next, referring to FIG. 10, the gate insulating film 122, the gate electrode 132, and the source/drain region 140 are formed in the spherical recess trench 118, so that the spherical recess channel array transistor 20 is completed.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

According to the semiconductor integrated circuit device and the method of manufacturing the same, the following effects can be obtained.

First, even though adjacent recess trenches may be connected and a bridge may occur, a semiconductor integrated circuit device will not necessarily suffer a defect. Accordingly, manufacturing productivity can be improved.

Second, because of a reduction in the number of defective semiconductor integrated circuit devices due to a bridge, it is now possible to stably form a spherical recess channel array transistor with characteristics better than a recess channel array transistor.

Third, in a method of manufacturing a semiconductor integrated circuit device, since a part of the recess trench may be used as a dummy pattern, even and symmetrical recess trenches can be formed. Therefore, process stability may be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A photo mask comprising:
a light transmissive substrate;
a main light blocking pattern formed on the substrate and defining first and second light transmitting rows, the first and second light transmitting rows being adjacent to each other; and
an auxiliary light blocking pattern dividing each of the first light transmitting rows into a long portion and a short portion.

2. The photo mask of claim 1, wherein the first and second light transmitting rows are alternately arranged.

3. The photo mask of claim 1, wherein the first and second light transmitting rows are parallel.

4. The photo mask of claim 1, wherein the auxiliary light blocking pattern is polygonal.

5. The photo mask of claim 1, wherein the auxiliary light blocking pattern is circular.

6. The photo mask of claim 1, wherein one or more of the auxiliary light blocking patterns are formed in each of the first light transmitting rows.

7. The photo mask of claim 1, the auxiliary light blocking pattern having a width in one direction that is the same as a width of the first light transmitting rows and having a width in another direction that is larger than the resolution of an exposure.

8. The photo mask of claim 1, the auxiliary light blocking pattern having:
a width in one direction that is shorter than a width of the first light transmitting rows but larger than the resolution of an exposure;
a width in another direction that is larger than the resolution of the exposure; and
a gap between the auxiliary light blocking pattern and the auxiliary light blocking pattern that is smaller than the resolution of the exposure.

9. The photo mask of claim 8, wherein the auxiliary light blocking pattern is a rectangle.

10. The photo mask of claim 8 wherein the auxiliary light blocking pattern is a polygon.

11. The photo mask of claim 1, the auxiliary light blocking pattern having:
a width in one direction that is the same as a width of the first light transmitting rows;
a width of adjacent portions of the auxiliary light blocking patterns each have a width in another direction that is larger than a resolution of the exposure; and
a gap formed between adjacent portions of the auxiliary light blocking patterns that has a width in another direction that is less than the resolution of the exposure.

12. The photo mask of claim 11, wherein the widths of adjacent portions of the auxiliary light blocking patterns are the same.

13. The photo mask of claim 12, the auxiliary light blocking pattern having a circular or elliptical shape and having a diameter that is larger than the resolution of an exposure.

14. A semiconductor integrated circuit comprising:
a semiconductor substrate;
a first recess trench extending in a first direction on the semiconductor substrate;
a second recess trench adjacent to the first recess trench, having a length smaller than the first recess trench, and having one end aligned with one end of the first recess trench in a second direction; and
a third recess trench having one end opposite to the other end of the second recess trench, the second and third trenches aligned with each other in the first direction.

15. The device of claim 14, wherein the first and third recess trenches are alternately arranged in the second direction.

16. The device of claim 14, wherein the first, second, and third recess trenches are spherical recess trenches.

17. The device of claim 14, wherein a termination width of each of the first, second, and third recess trenches is larger than the width of other regions of the first, second, and third recess trenches, respectively.

18. The device of claim 14, further comprising:
a gate insulating film conformably formed inside the first, second, and third recess trenches;
a gate electrode formed on the gate insulating film; and
source/drain regions aligned with the gate electrode.

19. The device of claim 14, wherein the first direction and the second direction are perpendicular to each other.

20. A method of manufacturing a semiconductor integrated circuit, the method comprising:
forming a photo mask comprising;
a light transmissive substrate,
a main light blocking pattern formed on the substrate and defining first and second light transmitting rows, the first and second light transmitting rows being adjacent to each other, and
an auxiliary light blocking pattern dividing each of the first light transmitting rows into a long portion and a short portion; and
forming recess trenches in a semiconductor substrate using the photo mask to block light.

21. The method of claim 20, further comprising forming dummy transistors in one of the recess trenches that is defined by the short portion.

22. The method of claim 20, wherein the first and second light transmitting rows are alternately arranged.

23. The photo mask of claim 20, wherein the first and second light transmitting rows are parallel.

24. The method of claim 20, wherein termination widths of each of the recess trenches is larger than the width of other regions of the recess trenches, respectively.

25. The method of claim 20, wherein forming the recess trenches comprises:
forming a pad insulating film and a mask film on the semiconductor substrate;
patterning the mask film using the photo mask to form a mask film pattern; and
etching the pad insulating film and the semiconductor substrate using the mask film pattern as a mask to form the recess trenches.

26. The method of claim 20, wherein the recess trenches are spherical recess trenches.

27. The method of claim 26, wherein forming the spherical recess trenches comprises:
forming a pad insulating film and a mask film on the semiconductor substrate;
patterning the mask film using the photo mask to form a mask film pattern;
etching the pad insulating film and the semiconductor substrate using the mask film pattern as a mask to form the recess trenches; and
isotropically etching bottoms of the recess trenches to form spherical recess trenches whose bottoms are spherical.

28. The method of claim 20, further comprising:
after forming the recess trenches,
conformably forming a gate insulating film inside the recess trenches;
forming a gate electrode on the gate insulating film; and
forming source/drain regions aligned with the gate electrode.
